(19) United States
(12) Patent Application Publication
(10) Pub. No.: US 2026/0182099 A1
(43) Pub. Date: Jun. 25, 2026

(54) DISPLAY DEVICE

(71) Applicant: LG Display Co., Ltd., Seoul (KR)

(72) Inventors: Jusang RHIM, Seoul (KR); RokHee LEE, Seoul (KR); Sunghwan YOON, Seoul (KR); MinSeok KIM, Seoul (KR)

(73) Assignee: LG Display Co., Ltd., Seoul (KR)

(21) Appl. No.: 19/357,893

(22) Filed: Oct. 14, 2025

(30) Foreign Application Priority Data
Dec. 24, 2024 (KR) 10-2024-0196068

(51) Int. Cl. H10H 20/84; H10H 20/01; H10H 20/821; H10H 20/831; H10H 20/832; H10H 20/833

(52) U.S. Cl. CPC H10H 20/84; H10H 20/032; H10H 20/034; H10H 20/821; H10H 20/831; H10H 20/833; H10H 20/835

(57) ABSTRACT

A display device includes a substrate defining a plurality of sub-pixels, with a plurality of light emitting elements positioned in each sub-pixel of the plurality of sub-pixels on the substrate. An insulating layer is provided on the substrate, the insulating layer having an upper end in contact with the plurality of light emitting elements to secure them in place. A plurality of air gaps is formed between the insulating layer and the plurality of light emitting elements, the air gaps being disposed at lower side portions of the light emitting elements to reduce mechanical stress, prevent short circuits, and enhance optical performance. This structure allows the light emitting elements to be stably fixed while improving process reliability and display quality.

### CROSS-REFERENCE TO RELATED APPLICATIONS

This application claims the priority of Korean Patent Application No. 10-2024-0196068 filed on Dec. 24, 2024, in the Korean Intellectual Property Office, the disclosure of which is incorporated herein by reference.

### BACKGROUND

### Technical Field

The present disclosure relates to a display device, and more particularly, to a display device in which a self-assembled light emitting element is stably fixed.

### Description of the Related Art

In display devices used for computer monitors, televisions, or mobile phones, there are organic light emitting display devices (OLEDs) that emit light by themselves, and liquid crystal display devices (LCDs) that require a separate light source.

The applicable range of display devices is being diversified from computer monitors and televisions to personal portable devices, and research is being conducted on display devices having a large display area while having reduced volume and weight.

In addition, recently, display devices including a light emitting diode (LED) have been attracting attention as next-generation display devices. Since an LED is made of an inorganic material rather than an organic material, it has excellent reliability and a longer lifespan compared to liquid crystal display devices and organic light emitting display devices. Furthermore, the LED not only has a fast turn-on speed but also exhibits high light emission efficiency, strong impact resistance, excellent stability, and can display high-luminance images.

### BRIEF SUMMARY

The disclosed display device introduces a thermoplastic insulating layer that undergoes heat treatment and molding after self-assembly to physically enclose the upper sides of the light emitting elements. This structure stabilizes the elements on the substrate, preventing detachment or tilt during cleaning or spin coating, without requiring smaller openings that could cause jamming or misalignment. In addition, air gaps are formed between the insulating layer and the lower sides of the light emitting elements, reducing mechanical stress, preventing short circuits, and improving optical performance by minimizing unwanted light absorption.

The device also features a multi-layer electrode structure including a transparent first connection electrode and a reflective second connection electrode. This configuration not only provides reliable electrical connections through contact holes with controlled dimensions but also improves light output efficiency by reflecting light toward the display side while suppressing external reflections. Incorporating black materials into the insulating layer removes the need for a separate black matrix, reducing display thickness and simplifying the manufacturing process.

Finally, dielectrophoresis is employed for the self-assembly of light emitting elements, enabling precise and large-scale placement suitable for micro light emitting diode and other high-resolution display applications. Together with the fixing method and optical enhancements, these features improve manufacturing yield, process reliability, and production cost efficiency, making the technology advantageous for next-generation displays.

For example, various embodiments of the present disclosure provide a display device in which a self-assembled light emitting element is stably fixed.

Various embodiments of the present disclosure provide a display device in which the fixing force of the light emitting element is secured, thereby improving the manufacturing process.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate in which a plurality of sub-pixels is defined, a plurality of light emitting elements in each of the plurality of sub-pixels on the substrate, and an insulating layer on the substrate and having an upper end in contact with the plurality of light emitting elements. A plurality of air gaps is disposed between the insulating layer and the plurality of light emitting elements.

Other detailed matters of the exemplary embodiments are included in the detailed description and the drawings.

According to an exemplary embodiment of the present disclosure, the fixing force of the light emitting element may be improved, thereby realizing process optimization.

According to an exemplary embodiment of the present disclosure, since the light emitting element is stably fixed, the manufacturing process of the display device may be stably carried out.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an exemplary embodiment of the present disclosure;

FIG. 2 is an enlarged plan view of a display device according to an exemplary embodiment of the present disclosure;

FIG. 3 is an enlarged cross-sectional view of a display device according to an exemplary embodiment of the present disclosure; and

FIGS. 4A to 4E are views for explaining a method of manufacturing a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

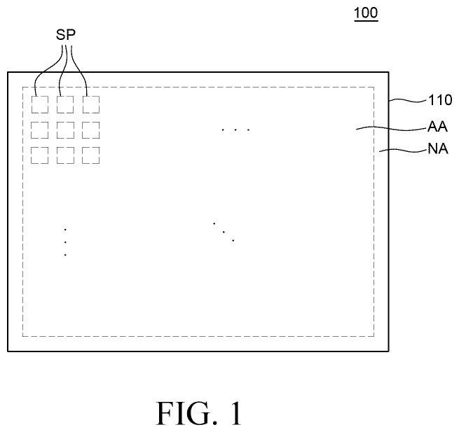

FIG. 1 is a schematic plan view of a display device according to an exemplary embodiment of the present disclosure. In FIG. 1, for convenience of description, only the substrate 110 among various components of the display device 100 is illustrated.

Referring to FIG. 1, the substrate 110 may serve as a component for supporting various components included in the display device 100 and may be formed of an insulating material. For example, the substrate 110 may be formed of glass or resin. In addition, the substrate 110 may be formed of a polymer or plastic, and in some exemplary embodiments, the substrate 110 may be formed of a plastic material having flexibility. A plurality of sub-pixels SP may be formed on the substrate 110, and an image may be displayed therein.

The substrate 110 may define an active area AA and a non-active area NA.

The active area AA is an area where an image is displayed in the display device 100. A plurality of sub-pixels SP may be disposed in the active area AA. The plurality of sub-pixels SP is the minimum unit constituting the active area AA, and may include a plurality of light emitting elements to emit light. The plurality of sub-pixels SP may display light of various colors such as red light, green light, and blue light, and may display images of various colors through their combinations. The plurality of light emitting elements may be differently defined according to the type of the display device 100. For example, when the display device 100 is an inorganic light emitting display device 100, the light emitting elements may be light emitting diodes (LEDs) or micro light emitting diodes (micro-LEDs).

In the active area AA, a plurality of signal lines for transmitting various signals to the plurality of sub-pixels SP is disposed. For example, the plurality of signal lines may include a plurality of power lines for supplying a power voltage to each of the plurality of sub-pixels SP.

The non-active area NA may be defined as an area in which an image is not displayed and which extends from the active area AA. In the non-active area NA, link lines and pad electrodes for transmitting signals to the sub-pixels SP of the active area AA, or driving ICs may be disposed. Meanwhile, the non-active area NA may be located on the rear surface of the display device 100, i.e., a surface where no sub-pixels SP are present, or may be omitted, and is not limited to the illustrated drawings.

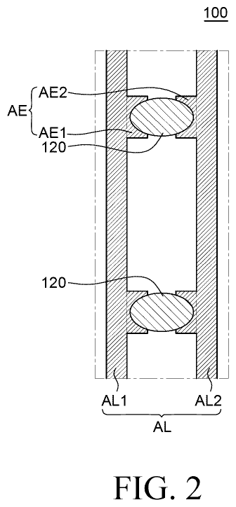

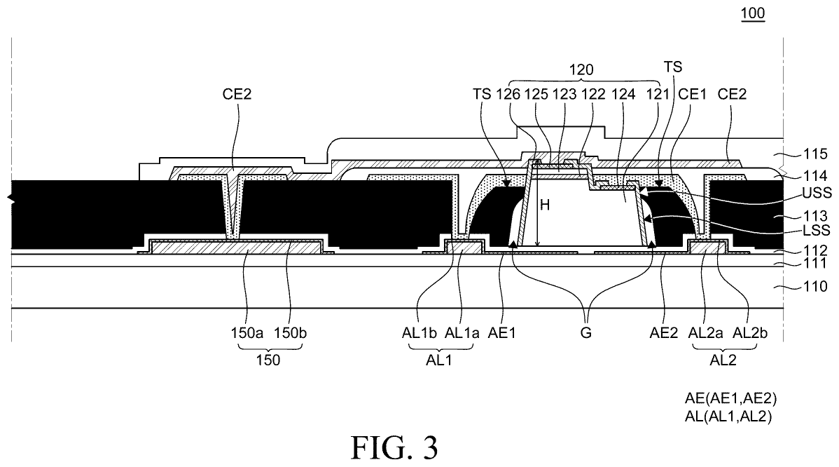

Hereinafter, with reference to FIGS. 2 and 3, the active area AA of the display device according to an exemplary embodiment of the present disclosure will be described in detail.

FIG. 2 is an enlarged plan view of a display device according to an exemplary embodiment of the present disclosure. FIG. 3 is an enlarged cross-sectional view of a display device according to an exemplary embodiment of the present disclosure. FIG. 2 is an enlarged plan view of two adjacent sub-pixels among the plurality of sub-pixels. FIG. 3 is an enlarged cross-sectional view of one sub-pixel among the plurality of sub-pixels.

Referring to FIGS. 2 and 3, the display device 100 includes a substrate 110, a first insulating layer 111, a second insulating layer 112, a third insulating layer 113, a fourth insulating layer 114, a fifth insulating layer 115, a contact electrode 150, a plurality of light emitting elements 120, a plurality of assembly lines AL, a plurality of assembly electrodes AE, a first connection electrode CE1, and a second connection electrode CE2.

First, the first insulating layer 111 is disposed on the substrate 110. The first insulating layer 111 is an insulating layer for protecting configurations beneath the first insulating layer 111 and may be formed of a single layer or multiple layers of silicon oxide (SiOx) or silicon nitride (SiNx), but is not limited thereto.

A plurality of assembly lines AL, a plurality of assembly electrodes AE, and a plurality of contact electrodes 150 may be disposed on the first insulating layer 111.

The plurality of contact electrodes 150 is electrodes electrically connected to second connection electrodes CE2, which will be described later. Each of the plurality of contact electrodes 150 may be formed of a plurality of conductive layers. For example, the plurality of contact electrodes 150 may include a first contact electrode 150a and a second contact electrode 150b disposed to cover the first contact electrode 150a. The first contact electrode 150a may be formed of a conductive layer having excellent conductivity, and the second contact electrode 150b may be formed of a clad layer resistant to corrosion. For example, the first contact electrode 150a may be formed of conductive materials such as copper (Cu) and chromium (Cr), while the second contact electrode 150b may be formed of materials such as molybdenum (Mo) or molybdenum titanium (MoTi) to have a robust structure against corrosion, but the exemplary embodiments of the present disclosure are not limited thereto.

The plurality of assembly lines AL generates an electric field for self-assembling the plurality of light emitting elements 120 during the manufacture of the display device 100, and serves as wiring lines for supplying driving voltages to the plurality of light emitting elements 120 during the driving of the display device 100. The plurality of assembly lines AL may be disposed along a plurality of sub-pixels SP disposed in the same line. The plurality of assembly lines AL may be disposed to overlap a plurality of sub-pixels SP disposed in the same column. For example, a first assembly line AL1 and a second assembly line AL2 may be disposed along the plurality of sub-pixels SP disposed in the same column.

Each of the plurality of assembly lines AL may include a conductive layer having excellent conductivity and a clad layer covering the conductive layer. Referring to FIG. 3, each of the plurality of first assembly lines AL1 may include a first conductive layer AL1a and a first clad layer AL1b, and each of the plurality of second assembly lines AL2 may include a second conductive layer AL2a and a second clad layer AL2b. The first conductive layer AL1a and the second conductive layer AL2a may be formed of a conductive layer having excellent conductivity, such as copper (Cu) and chromium (Cr), and the first clad layer AL1b and the second clad layer AL2b may be formed of a clad layer having strong corrosion resistance, such as molybdenum (Mo) or molybdenum titanium (MoTi).

The plurality of assembly lines AL includes the plurality of first assembly lines AL1 and the plurality of second assembly lines AL2. The plurality of first assembly lines AL1 and the plurality of second assembly lines AL2 may be alternately disposed. The plurality of first assembly lines AL1 and the plurality of second assembly lines AL2 may be disposed apart from each other at regular intervals. In each of the plurality of sub-pixels SP, one first assembly line AL1 and one second assembly line AL2 may be disposed adjacent to each other. During the driving of the display device 100, different driving voltages are applied to the plurality of first assembly lines AL1 and the plurality of second assembly lines AL2, thereby driving the plurality of light emitting elements 120 in a passive matrix (PM) manner.

When the plurality of light emitting elements 120 is driven in a passive matrix manner, the display device 100 may be used as a lighting device. For example, the display device 100 may be used as a lighting device capable of displaying various colors and luminance by turning on or off all or some of the plurality of light emitting elements 120. The display device 100 is not limited thereto and may be driven in an active matrix (AM) manner by further including a driving element such as a driving transistor.

On the substrate 110, a plurality of assembly electrodes AE is disposed in each of the plurality of sub-pixels SP. The plurality of assembly electrodes AE includes a plurality of first assembly electrodes AE1 and a plurality of second assembly electrodes AE2. The plurality of first assembly electrodes AE1 may be connected to the plurality of first assembly lines AL1, and the plurality of second assembly electrodes AE2 may be connected to the plurality of second assembly lines AL2. A pair of the first assembly electrode AE1 and the second assembly electrode AE2 may be disposed adjacent to each other to form an electric field for self-assembling a light emitting element 120. Each of the pair of the first assembly electrode AE1 and the second assembly electrode AE2 may be disposed to overlap with the position where the light emitting element 120 is disposed in each of the plurality of sub-pixels SP.

The plurality of assembly electrodes AE may be formed of a conductive material, for example, copper (Cu), chromium (Cr), molybdenum (Mo), or molybdenum titanium (MoTi), but is not limited thereto.

By applying a voltage to the plurality of assembly lines AL and the plurality of assembly electrodes AE, the plurality of light emitting elements 120 may be self-assembled in each of the plurality of sub-pixels SP. For example, an alternating current voltage may be applied to the plurality of first assembly lines AL1 and the plurality of first assembly electrodes AE1, and to the plurality of second assembly lines AL2 and the plurality of second assembly electrodes AE2, so that an electric field may be formed. By this electric field, the light emitting element 120 may be dielectrically polarized to have polarity. The dielectrically polarized light emitting element 120 may then move or be fixed in a specific direction due to dielectrophoresis DEP, that is, the electric field. Accordingly, the plurality of light emitting elements 120 may be self-assembled in the plurality of sub-pixels SP using dielectrophoresis.

Next, a second insulating layer 112 is disposed on the plurality of contact electrodes 150, the plurality of assembly lines AL, and the plurality of assembly electrodes AE. The second insulating layer 112 may be an insulating layer for protecting the configuration below the second insulating layer 112, and may be formed of a single layer or a multi-layer of silicon oxide (SiOx) or silicon nitride (SiNx), but is not limited thereto.

Next, a light emitting element 120 is disposed in the region between a pair of the first assembly electrode AE1 and the second assembly electrode AE2. The light emitting element 120 includes a first semiconductor layer 121, an emission layer 122, a second semiconductor layer 123, a first electrode 124, a second electrode 125, and an encapsulation film 126.

First, the first semiconductor layer 121 is disposed on the plurality of assembly electrodes AE, and the second semiconductor layer 123 is disposed on the first semiconductor layer 121. The first semiconductor layer 121 and the second semiconductor layer 123 may be semiconductor layers doped with n-type and p-type impurities. For example, each of the first semiconductor layer 121 and the second semiconductor layer 123 may be a semiconductor layer formed of a material such as gallium nitride (GaN), indium aluminum phosphide (InAIP), or gallium arsenide (GaAs) doped with n-type and p-type impurities. The p-type impurity may include magnesium (Mg), zinc (Zn), or beryllium (Be), and the n-type impurity may include silicon (Si), germanium (Ge), or tin (Sn), but is not limited thereto.

An emission layer 122 is disposed between the first semiconductor layer 121 and the second semiconductor layer 123. The emission layer 122 may emit light by receiving holes and electrons from the first semiconductor layer 121 and the second semiconductor layer 123. The emission layer 122 may be formed as a single layer or a multi-quantum well (MQW) structure, and may be formed, for example, of indium gallium nitride (InGaN) or gallium nitride (GaN), but is not limited thereto.

A first electrode 124 is disposed on the first semiconductor layer 121. The first electrode 124 is an electrode for electrically connecting the first connection electrode CE1 and the first semiconductor layer 121. The first electrode 124 may be disposed on the top surface of the first semiconductor layer 121 exposed from the emission layer 122 and the second semiconductor layer 123. One or more first electrodes 124 may be disposed on the top surface of the first semiconductor layer 121. The first electrode 124 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, but is not limited thereto.

A second electrode 125 is disposed on the second semiconductor layer 123. The second electrode 125 may be disposed on the top surface of the second semiconductor layer 123. The second electrode 125 is an electrode for electrically connecting the second connection electrode CE2 and the second semiconductor layer 123. The second electrode 125 may be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, but is not limited thereto.

Next, the encapsulation film 126 enclosing the first semiconductor layer 121, the emission layer 122, the second semiconductor layer 123, the first electrode 124, and the second electrode 125 is disposed. The encapsulation film 126 is made of an insulating material and may protect the first semiconductor layer 121, the emission layer 122, and the second semiconductor layer 123. The encapsulation film 126 may be disposed to cover the side surface and top surface of the first semiconductor layer 121, the side surface of the emission layer 122, the side surface and top surface of the second semiconductor layer 123, the first electrode 124 and the second electrode 125. A contact hole may be formed in the encapsulation film 126 to expose the first electrode 124 and the second electrode 125, so that the first connection electrode CE1 and the second connection electrode CE2 may be electrically connected to the first electrode 124 and the second electrode 125 respectively.

A third insulating layer 113 is disposed on the plurality of assembly lines AL and the plurality of assembly electrodes AE. The third insulating layer 113 may be disposed to cover the upper portion of the substrate 110 on which the plurality of assembly lines AL and the plurality of assembly electrodes AE are formed.

The third insulating layer 113 may be formed of a single layer or multiple layers of an organic insulating material and may be made of a thermoplastic resin. Meanwhile, the third insulating layer 113 may include a black material. For example, the third insulating layer 113 may include black components having a high light absorption rate. Accordingly, the third insulating layer 113 may suppress color mixing that may occur between light emitting elements (120) emitting light of different colors and may suppress external light reflection.

The third insulating layer 113 may be disposed to cover the light emitting elements 120. For example, the third insulating layer 113 may include a portion contacting the side surfaces of the plurality of light emitting elements 120. The upper end of the third insulating layer 113 may be in contact with the upper side surfaces of the plurality of light emitting elements 120. Accordingly, the third insulating layer 113 may be disposed to cover the light emitting elements 120, so that the light emitting elements 120 may be fixed on the substrate 110 and protected. Meanwhile, referring to FIG. 3, the third insulating layer 113 may include a portion disposed to be spaced apart from the lower side surfaces of the plurality of light emitting elements 120.

The third insulating layer 113 may include a first contact hole exposing top surfaces of the plurality of assembly lines AL and/or the plurality of assembly electrodes AE, and a second contact hole exposing top surfaces of the plurality of contact electrodes 150. In this case, from the lower side to the upper side of the plurality of light emitting elements 120, the difference between the width of the plurality of first contact holes and the width of the plurality of second contact holes may increase. For example, from the lower side to the upper side of the plurality of light emitting elements 120, the width of the plurality of first contact holes may be larger than the width of the plurality of second contact holes.

A plurality of air gaps G may be disposed between the third insulating layer 113 and the plurality of light emitting elements 120, in which the third insulating layer 113 is spaced apart from the plurality of light emitting elements 120. For example, the plurality of air gaps G may be disposed on the lower side surfaces of the plurality of light emitting elements 120. In addition, the plurality of air gaps G may overlap with the plurality of first assembly electrodes AE1 and the plurality of second assembly electrodes AE2. Accordingly, the plurality of air gaps G may expose a portion of the side surfaces of the plurality of light emitting elements 120 from the third insulating layer 113.

Referring to FIG. 3, each light emitting element 120 may have an upper region and a lower region. The upper region may include an upper side surface USS positioned near a light emission side of the display device 100, whereas the lower region may include a lower side surface LSS positioned adjacent the substrate 110. The terms “upper” and “lower” may refer to relative positions along a vertical direction perpendicular to the main plane of the substrate 110, with the upper side surface USS located farther from the substrate 110 than the lower side surface LSS.

In some embodiments, the upper region of each light emitting element 120 may encompass portions near the emission layer 123 and second electrode 125, while the lower region may encompass portions near the first semiconductor layer 121 and first electrode 124. Accordingly, the light emitting element 120 may be described as having the upper side surface USS surrounding the upper region and the lower side surface LSS surrounding the lower region, with the side surfaces extending vertically along the height H of the light emitting element 120.

On the third insulating layer 113, a first connection electrode CE1 may be disposed in each of the plurality of sub-pixels SP. The first connection electrode CE1 is an electrode for electrically connecting the light emitting element 120 with the first assembly line AL1 and/or the first assembly electrode AE1. For example, the first connection electrode CE1 may be disposed in the first contact hole formed in the third insulating layer 113 to be electrically connected with the first assembly line AL1 and/or the first assembly electrode AE1. In addition, the first connection electrode CE1 may be connected to any one of the plurality of first electrodes 124 of the light emitting elements 120. Therefore, the first electrode 124 and the first semiconductor layer 121 of the light emitting element 120 may be electrically connected to the first assembly line AL1 and/or the first assembly electrode AE1 through the first connection electrode CE1. At this time, the first connection electrode CE1 may extend over the light emitting element 120 and may directly contact the top surface of the third insulating layer 113.

The first connection electrode CE1 may be formed of a transparent conductive material. For example, the first connection electrode CE1 may be formed of a transparent conductive material such as indium tin oxide (ITO) or indium zinc oxide (IZO), but is not limited thereto.

A fourth insulating layer 114 may be disposed on the third insulating layer 113. The fourth insulating layer 114 may be disposed on the first connection electrode CE1 to fill the first contact hole of the third insulating layer 113. The fourth insulating layer 114 may be formed of a single layer or a multi-layer of an organic insulating material. For example, the fourth insulating layer 114 may be formed of benzocyclobutene or an acryl-based organic material, but is not limited thereto.

A second connection electrode CE2 may be disposed in each of the plurality of sub-pixels SP on the fourth insulating layer 114. The second connection electrode CE2 is an electrode for electrically connecting the light emitting element 120 with the plurality of contact electrodes 150. For example, the second connection electrode CE2 may be disposed on the third insulating layer 113 to be electrically connected with the plurality of contact electrodes 150. In addition, the second connection electrode CE2 may be connected to the second electrode 125 of the light emitting element 120.

At this time, the second connection electrode CE2 may overlap the light emitting element 120 and may also be disposed to overlap the first connection electrode CE1 with the fourth insulating layer 114 interposed therebetween.

The second connection electrode CE2 may be formed of a reflective conductive material. For example, the second connection electrode CE2 may be formed of an opaque reflective conductive material such as copper (Cu), aluminum (Al), molybdenum (Mo), nickel (Ni), titanium (Ti), chromium (Cr), or an alloy thereof. Accordingly, the second connection electrode CE2 may function as a reflector that reflects light emitted from the plurality of light emitting elements 120 toward the lower side of the substrate 110.

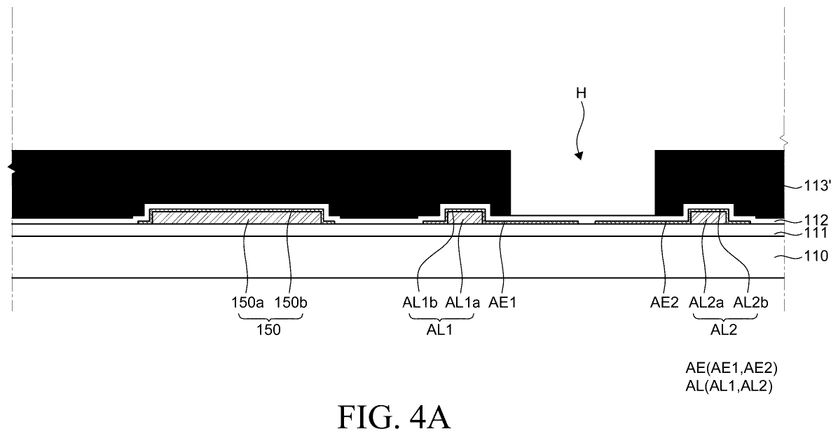

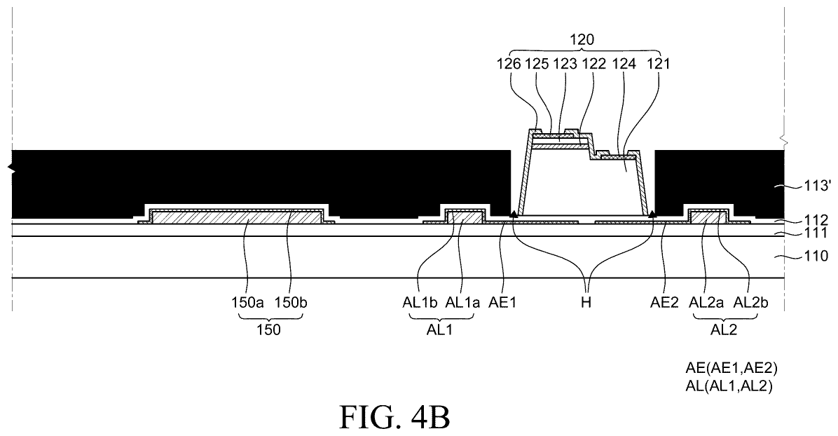

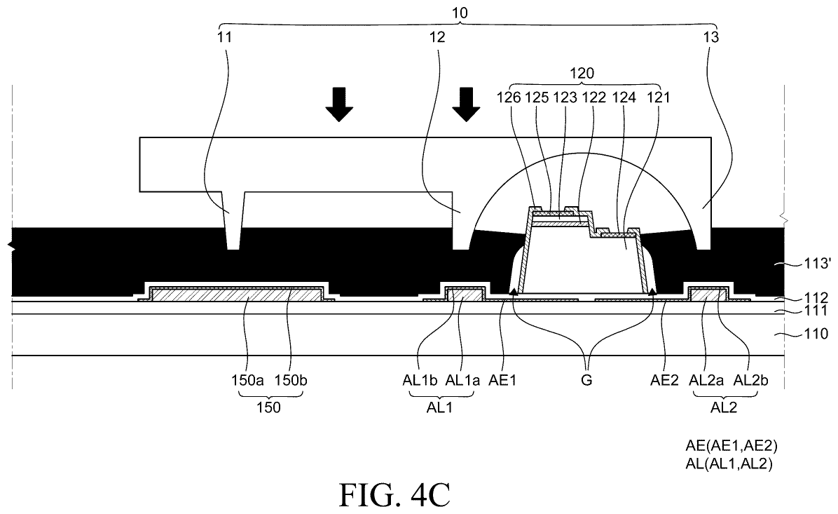

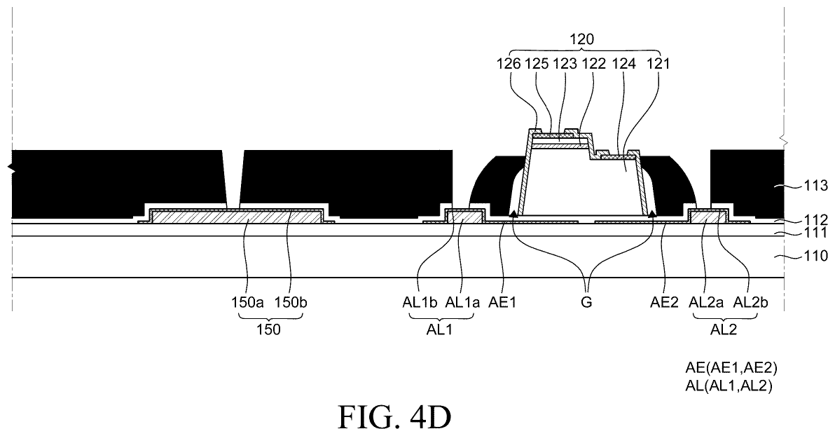

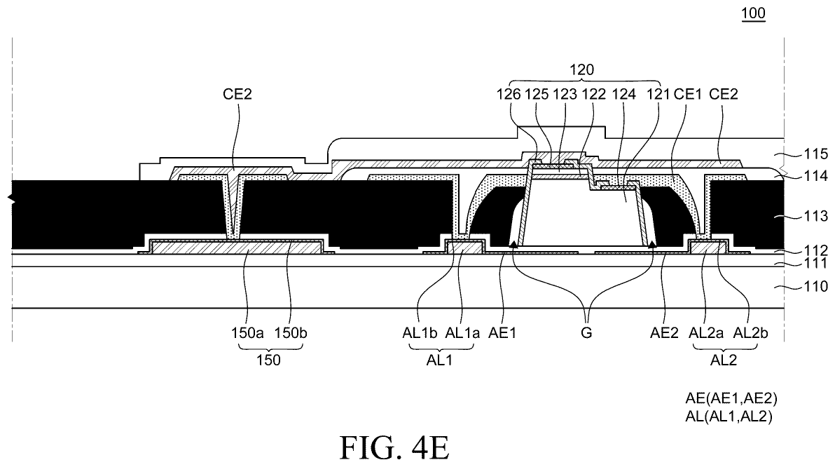

Hereinafter, with reference to FIGS. 4A to 4E, a method of manufacturing the display device 100 according to an exemplary embodiment of the present disclosure will be described.

FIGS. 4A to 4E are views illustrating a method of manufacturing the display device according to an exemplary embodiment of the present disclosure.

First, referring to FIG. 4A, a first insulating layer 111, a plurality of assembly lines AL, a plurality of assembly electrodes AE, a plurality of contact electrodes 150, and a second insulating layer 112 are formed on the substrate 110.

Subsequently, an initial insulating layer 113′ having an opening H is formed on the second insulating layer 112. The opening H may correspond to a region in which the light emitting element 120 is self-assembled. The opening H may overlap the plurality of assembly electrodes AE. In this case, the width of the opening H may be greater than the maximum width of the light emitting element 120 so that the light emitting element 120 may be stably seated within the opening H. Accordingly, the initial insulating layer 113′ may not be in contact with the light emitting element 120 that is self-assembled in the opening H.

At this time, the thickness of the initial insulating layer 113′ may be greater than the thickness of the first semiconductor layer 121 disposed under the first electrode 124 of the light emitting element 120. For example, the top surface of the initial insulating layer 113′ may be positioned between the bottom surface of the first electrode 124 and the top surface of the second electrode 125.

Referring to FIG. 4B, the light emitting element 120 is self-assembled inside the opening H of the initial insulating layer 113′. For example, the substrate 110 on which the initial insulating layer 113′ is formed and the light emitting element 120 are introduced into a chamber filled with fluid, and an alternating current voltage is applied to the plurality of assembly lines AL and the plurality of assembly electrodes AE to form an electric field. At this time, the light emitting element 120 may be dielectrically polarized by the electric field to have polarity. The dielectrically polarized light emitting element 120 may then be self-assembled inside the opening H above the plurality of assembly electrodes AE by dielectrophoresis (DEP), that is, the electric field.

After the self-assembly is completed, the fluid may be evaporated. At this time, until the fluid is completely evaporated, the electric field may be formed in the plurality of assembly lines AL and the plurality of assembly electrodes AE so that the light emitting element 120 remains fixed inside the opening H. When the fluid is completely evaporated, the electric field may be removed. Even after the electric field is removed, the light emitting element 120 may remain temporarily fixed on the substrate 110 by van der Waals force.

Referring to FIG. 4C, a molding process is performed to form a plurality of contact holes in the initial insulating layer 113′. For example, in order to facilitate deformation of the initial insulating layer 113′, a heat treatment process may be performed on the initial insulating layer 113′, followed by pressing the initial insulating layer 113′ with a mold 10.

The mold 10 includes a flat portion 11, and a first protrusion 12 and a second protrusion 13 disposed with the light emitting element 120 between them. The first protrusion 12 has a cylindrical and/or conical shape protruding toward the substrate 110. In contrast, the second protrusion 13 has a concave curved surface recessed toward the top surface of the mold 10, while its edges protrude toward the substrate 110. The first protrusion 12 is disposed to overlap with the plurality of contact electrodes 150, and the second protrusion 13 is disposed to overlap with the plurality of assembly lines AL. At this time, the center of the concave curved surface of the second protrusion 13 may be disposed to correspond to the light emitting element 120. Accordingly, in the process of pressing the initial insulating layer 113′ with the mold 10, the light emitting element 120 may not interfere with the second protrusion 13.

In the process of pressing the initial insulating layer 113′ with the mold 10, the first protrusion 12 and the second protrusion 13 are pressed toward the initial insulating layer 113′, and the shape of the initial insulating layer 113′ is deformed corresponding to the first protrusion 12 and the second protrusion 13. As the pressing depth of the second protrusion 13 into the initial insulating layer 113′ increases, inside the second protrusion 13, the initial insulating layer 113′ may move toward the central portion of the light emitting element 120 along the inner curved surface of the second protrusion 13. Accordingly, as illustrated in FIG. 4C, the upper end of the initial insulating layer 113′ may enclose the upper side surface of the light emitting element 120. As a result, a plurality of patterns corresponding to the first protrusion 12 and the second protrusion 13 may be formed in the initial insulating layer 113′. In addition, the initial insulating layer 113′ may be deformed so as to be spaced apart from the lower side surface of the light emitting element 120 while covering the upper side surface of the light emitting element 120. Thus, a plurality of air gaps G is formed between the initial insulating layer 113′ and the light emitting element 120.

Next, referring to FIG. 4D, a process of removing the initial insulating layer 113′ in which a plurality of patterns corresponding to the first protrusion 12 and the second protrusion 13 is formed, and the second insulating layer 112 overlapping the plurality of patterns, is performed. Accordingly, the second insulating layer 112 and the third insulating layer 113 are formed to include a contact hole exposing the top surfaces of the plurality of contact electrodes 150 and a contact hole exposing the top surfaces of the plurality of assembly lines AL.

Subsequently, referring to FIG. 4E, a first connection electrode CE1 is formed in the contact hole of the third insulating layer 113 exposing the top surfaces of the plurality of assembly lines AL, and a fourth insulating layer 114 is formed on the first connection electrode CE1. In addition, a second connection electrode CE2 is formed in the contact hole of the third insulating layer 113 exposing the top surfaces of the plurality of contact electrodes 150, and a fifth insulating layer 115 covering the first connection electrode CE1 and the second connection electrode CE2 is formed to complete the manufacturing process of the display device 100.

In order to address problems in which the light emitting element is trapped in the opening of the insulating layer during the self-assembly process and is assembled in an inclined state, the opening of the insulating layer is formed larger than the light emitting element. Subsequently, after the light emitting element is self-assembled on the substrate, another insulating layer is disposed to fill the spaced region between the opening and the light emitting element above the light emitting element, so that the light emitting element is fixed on the substrate. However, before the insulating layer covering the light emitting element is disposed, the self-assembled light emitting element is temporarily fixed on the substrate only by van der Waals force, and therefore, it may be vulnerable to external forces. Accordingly, during processes such as spin coating and cleaning carried out immediately after the self-assembly process, some of the light emitting elements may be lifted or tilted depending on the spin speed and discharge rate, and there may be a problem of being bounced out of the opening. Therefore, a problem in which the light emitting elements are lost may occur.

Accordingly, in the display device 100 according to an exemplary embodiment of the present disclosure, after the light emitting element 120 is self-assembled, a heat treatment and a molding process are performed on the third insulating layer 113 formed of a thermoplastic resin material, so that the self-assembled light emitting element 120 may be fixed to the substrate 110. Accordingly, the third insulating layer 113 fixes the light emitting element 120 on the substrate 110 by a force enclosing the light emitting element 120, that is, physical force, and thus detachment of the light emitting element 120 during subsequent processes such as a cleaning process immediately after the self-assembly process may be suppressed. Therefore, the cleaning process can be carried out immediately after the self-assembly process without a risk of losing the light emitting element 120, which is advantageous for foreign material management.

In addition, even if the opening H of the initial insulating layer 113′ is formed larger than the size of the light emitting element 120 during the manufacturing process of the display device 100, the light emitting element 120 may be stably fixed to the substrate 110 through the heat treatment and molding processes of the initial insulating layer 113′. Accordingly, it is unnecessary to excessively reduce the size of the opening H in order to secure the fixing force of the light emitting element 120, and thus problems such as jamming of the light emitting element 120 and a tilt issue may be suppressed. As a result, short-circuit issues among the first connection electrode CE1, the second connection electrode CE2, and the light emitting element 120 may be suppressed.

Furthermore, in the display device 100 according to an exemplary embodiment of the present disclosure, since the third insulating layer 113 enclosing the side surface of the light emitting element 120 includes a black material, reflection of external light caused by the second connection electrode CE2 may be suppressed. Therefore, a separate structure including a black material, for example, a black bank, may not be required on the upper portion of the light emitting element 120. Accordingly, the thickness of the display device 100 may be reduced, and the number of processes and masks required for forming a black bank may be decreased. As a result, process cost and time may be reduced, thereby implementing process optimization.

The exemplary embodiments of the present disclosure can also be described as follows:

As shown in FIG. 3, a display device 100 may include a substrate 110 having at least one sub-pixel SP defined therein. A light emitting element 120 may be disposed in the sub-pixel SP on the substrate 110. An insulating layer 113 may be formed on the substrate 110 such that the insulating layer 113 laterally surrounds side surfaces of the light emitting element 120 while being spaced apart from lower side surfaces LSS of the light emitting element 120. An air gap G may be defined between the insulating layer 113 and the lower side surfaces LSS of the light emitting element 120.

In some embodiments, and as further illustrated in FIG. 3, the insulating layer 113 may contact the upper side surfaces USS of the light emitting element 120 while remaining spaced apart from the lower side surfaces LSS by the air gap G. This arrangement may secure the light emitting element 120 in position via the upper contact regions of the insulating layer 113 while preserving the air gap G along the lower side surfaces LSS to provide thermal and structural benefits.

As shown in FIG. 3, the air gap G may extend vertically along at least one-half of a height H of the light emitting element 120. The vertical extent of the air gap G may therefore correspond to a substantial portion of the light emitting element 120, ensuring that the lower regions of the light emitting element 120 remain physically isolated from the insulating layer 113.

Referring to FIG. 4C3, each light emitting element 120 may include a first semiconductor layer 121, a second semiconductor layer 122, and an emission layer 123 disposed between the first semiconductor layer 121 and the second semiconductor layer 122. A first electrode 124 may be disposed on the first semiconductor layer 121, and a second electrode 125 may be disposed on the second semiconductor layer 122. An encapsulation film 126 may enclose the first semiconductor layer 121, the emission layer 123, the second semiconductor layer 122, the first electrode 124, and the second electrode 125 to protect the light emitting element 120 from environmental degradation, as shown in FIG. 4C3.

As shown in FIG. 3, the display device 100 may further include a first connection electrode CE1 extending across a top surface TS of the insulating layer 113 to electrically connect to the first electrode 124 of the light emitting element 120. A second connection electrode CE2 may be disposed above the first connection electrode CE1, with the second connection electrode CE2 being electrically connected to the second electrode 125 of the light emitting element 120. A first assembly line AL1 and a second assembly line AL2 may be disposed on the substrate 110 and spaced apart from each other, as shown in FIG. 3. A first assembly electrode AE1 may be electrically connected to the first assembly line AL1, and a second assembly electrode AE2 may be electrically connected to the second assembly line AL2, with the first assembly electrode AE1 and the second assembly electrode AE2 disposed on opposite sides of the light emitting element 120. The first assembly line AL1, the second assembly line AL2, the first assembly electrode AE1, and the second assembly electrode AE2 may be disposed beneath the insulating layer 113 on the substrate 110, wherein the first assembly electrode AE1 and the second assembly electrode AE2 may be positioned to overlap the air gap G in plan view, as depicted in FIG. 3.

In the embodiment, the first connection electrode CE1 may extend into the insulating layer 113 to electrically connect with either the first assembly line AL1, the second assembly line AL2, or both. According to FIG. 3, the first connection electrode CE1 electrically connects to both the first assembly line AL1 and the second assembly line AL2.

As shown in FIG. 3, the first assembly line AL1 and the second assembly line AL2 may each include a conductive base layer and a clad layer disposed on the conductive base layer 111 to enhance conductivity and protect against oxidation or other environmental effects. The combination of the conductive base layers and the clad layers may improve the durability and electrical performance of the assembly lines AL1, AL2. In some embodiments, the first connection electrode CE1 directly contacts the clad layers of the assembly lines.

As depicted in FIG. 3, the insulating layer 113 may include a black material configured to suppress external light reflection. The inclusion of the black material within the insulating layer 113 may improve the optical contrast of the display device 100 by reducing the amount of reflected ambient light entering the viewing plane of the display device 100.

The exemplary embodiments of the present disclosure can further be described as follows:

According to an aspect of the present disclosure, a display device includes a substrate in which a plurality of sub-pixels is defined; a plurality of light emitting elements in each of the plurality of sub-pixels on the substrate; and an insulating layer on the substrate and having an upper end in contact with the plurality of light emitting elements. A plurality of air gaps is disposed between the insulating layer and the plurality of light emitting elements.

The plurality of air gaps may be disposed at lower side portions of the plurality of light emitting elements.

The insulating layer may be spaced apart from lower side surfaces of the plurality of light emitting elements and may contact upper side surfaces of the plurality of light emitting elements.

The display device may further include a first connection electrode electrically connected to the plurality of light emitting elements. The first connection electrode may extend over the plurality of light emitting elements and may contact a top surface of the insulating layer.

The display device may further include a second connection electrode electrically connected to the plurality of light emitting elements. The insulating layer may further include a plurality of first contact holes in which the first connection electrode is disposed and a plurality of second contact holes in which the second connection electrode is disposed. From lower to upper sides of the plurality of light emitting elements, a difference between widths of the plurality of first contact holes and the plurality of second contact holes may increase.

Each of the plurality of light emitting elements may include a first semiconductor layer; an emission layer on the first semiconductor layer; a second semiconductor layer on the emission layer; a first electrode on the first semiconductor layer; and a second electrode on the second semiconductor layer. The first connection electrode may be connected to the first electrode and the second connection electrode may be connected to the second electrode.

From lower to upper sides of the plurality of light emitting elements, widths of the plurality of first contact holes may be larger than widths of the plurality of second contact holes.

The display device may further include a plurality of first assembly electrodes and a plurality of second assembly electrodes spaced apart from the plurality of first assembly electrodes, in each of the plurality of sub-pixels. The plurality of first contact holes may expose top surfaces of the plurality of first assembly electrodes and top surfaces of the plurality of second assembly electrodes.

The plurality of air gaps may overlap the plurality of first assembly electrodes and the plurality of second assembly electrodes in an upper and down direction.

The second connection electrode may be disposed on the first connection electrode, the first connection electrode may include a transparent conductive material, and the second connection electrode may include a reflective conductive material.

The second connection electrode may overlap the first connection electrode and the plurality of light emitting elements in an upper and down direction.

The insulating layer may include a thermoplastic material and a black material

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate in which a plurality of sub-pixels is defined;
a plurality of light emitting elements in each of the plurality of sub-pixels on the substrate, each of the plurality of light emitting elements having an upper region including an upper side surface and a lower region including a lower side surface; and
an insulating layer on the substrate and having an upper end in contact with the upper side surfaces of the plurality of light emitting elements,
wherein a plurality of air gaps is disposed between the insulating layer and the plurality of light emitting elements.

2. The display device according to claim 1, wherein the plurality of air gaps is disposed along the lower side surface of the plurality of light emitting elements.

3. The display device according to claim 2, wherein the insulating layer is spaced apart from the lower side surface of the plurality of light emitting elements.

4. The display device according to claim 1, further comprising:
a first connection electrode electrically connected to the plurality of light emitting elements,
wherein the first connection electrode extends over the plurality of light emitting elements and contacts a top surface of the insulating layer.

5. The display device according to claim 4, further comprising:
a second connection electrode electrically connected to the plurality of light emitting elements,
wherein the insulating layer further includes a plurality of first contact holes in which the first connection electrode is disposed and a plurality of second contact holes in which the second connection electrode is disposed, and
wherein, from the lower region to the upper region of the plurality of light emitting elements, a difference between widths of the plurality of first contact holes and the plurality of second contact holes increases.

6. The display device according to claim 5, wherein each of the plurality of light emitting elements includes:
a first semiconductor layer;
an emission layer on the first semiconductor layer;
a second semiconductor layer on the emission layer;
a first electrode on the first semiconductor layer; and
a second electrode on the second semiconductor layer,
wherein the first connection electrode is connected to the first electrode and the second connection electrode is connected to the second electrode.

7. The display device according to claim 5, wherein, from the lower region to the upper region of the plurality of light emitting elements, widths of the plurality of first contact holes are larger than widths of the plurality of second contact holes.

8. The display device according to claim 5, further comprising:
a plurality of first assembly electrodes and a plurality of second assembly electrodes spaced apart from the plurality of first assembly electrodes, in each of the plurality of sub-pixels,
wherein the plurality of first contact holes exposes top surfaces of the plurality of first assembly electrodes and top surfaces of the plurality of second assembly electrodes.

9. The display device according to claim 8, wherein the plurality of air gaps overlaps the plurality of first assembly electrodes and the plurality of second assembly electrodes in a vertical direction.

10. The display device according to claim 5, wherein the second connection electrode is disposed on the first connection electrode,
wherein the first connection electrode includes a transparent conductive material, and
wherein the second connection electrode includes a reflective conductive material.

11. The display device according to claim 10, wherein the second connection electrode overlaps the first connection electrode and the plurality of light emitting elements in a vertical direction.

12. The display device according to claim 1, wherein the insulating layer includes a thermoplastic material and a black material.

13. A display device, comprising:
a substrate having a sub-pixel;
a light emitting element in the sub-pixel;
an insulating layer on the substrate, the insulating layer laterally surrounding side surfaces of the light emitting element and spaced apart from lower side surfaces of the light emitting element; and
an air gap defined between the insulating layer and the lower side surfaces of the light emitting element.

14. The display device according to claim 13, wherein the insulating layer contacts upper side surfaces of the light emitting element while remaining spaced apart from the lower side surfaces by the air gap.

15. The display device according to claim 13, wherein the air gap extends along at least one-half of a height of the light emitting element.

16. The display device according to claim 13, wherein the light emitting element includes:
a first semiconductor layer;
a second semiconductor layer;
an emission layer between the first semiconductor layer and the second semiconductor layer;
a first electrode on the first semiconductor layer;
a second electrode on the second semiconductor layer; and
an encapsulation film enclosing the first semiconductor layer, the emission layer, the second semiconductor layer, the first electrode, and the second electrode.

17. The display device according to claim 16, further comprising:
a first connection electrode extending across a top surface of the insulating layer to electrically connect to the first electrode of the light emitting element;
a second connection electrode disposed above the first connection electrode, the second connection electrode electrically connected to the second electrode of the light emitting element;
a first assembly line and a second assembly line disposed on the substrate and spaced apart from each other;
a first assembly electrode electrically connected to the first assembly line and a second assembly electrode electrically connected to the second assembly line, the first assembly electrode and the second assembly electrode disposed on opposite sides of the light emitting element,
wherein the first assembly line, the second assembly line, the first assembly electrode, and the second assembly electrode are disposed beneath the insulating layer on the substrate, and
wherein the first assembly electrode and the second assembly electrode are positioned to overlap the air gap in plan view.

18. The display device according to claim 17, wherein the first connection electrode extends into the insulating layer to electrically connect with either the first assembly line or the second assembly line or both.

19. The display device according to claim 17, wherein the first assembly line and the second assembly line include conductive base layers and clad layers disposed on the conductive base layers.

20. The display device according to claim 17, wherein the insulating layer includes a black material configured to suppress external light reflection.
